(19) United States
(12) Patent Application Publication
(10) Pub. No.: US 2011/0175126 A1
(43) Pub. Date: Jul. 21, 2011

(54) LIGHT-EMITTING DIODE STRUCTURE

(76) Inventors: Hung-Chih YANG, (US); Ming-Chi Hsu, (US); Ta-Cheng Hsu, (US); Chih-Chung Yang, (US); Tsung-Yi Tang, (US); Yung-Sheng Chen, (US); Wen-Yu Shiao, (US); Che-Hao Liao, (US); Yu-Jiun Shen, (US); Sheng-Horng Yen, (US)

(21) Appl. No.: 13/008,702

(22) Filed: Jan. 18, 2011

Related U.S. Application Data
(60) Provisional application No. 61/295,306, filed on Jan. 15, 2010.
(60) Provisional application No. 61/295,288, filed on Jan. 15, 2010.

(51) Int. Cl. H01L 31/0352; B82Y 99/00

(52) U.S. Cl. 257/98; 257/E31.032; 977/700

(57) ABSTRACT

A light emitting diode device is provided, which comprises a substrate comprising a first growth surface and a bottom surface opposite to the first growth surface; a dielectric layer with a plurality of openings therein formed on the first growth surface; a plurality of semiconductor nano-scaled structures formed on the substrate protruding through the openings; a layer formed on the plurality of semiconductor nano-scaled structures with a second growth surface substantially parallel with the bottom surface; a light emitting diode structure formed on the second growth surface; wherein the diameters of the openings are smaller than 250 nm, and wherein the diameters of the plurality semiconductor nano-scaled structures are larger than the diameters of the corresponding openings.

### REFERENCE TO RELATED APPLICATION

This application claims the right of priority based on US provisional application Ser. No. 61295306 and No. 61295288, filed Jan. 15, 2010, entitled “Growth of GaN Nanocolumns on Sapphire and GaN with Patterned Mask and The Applications Thereof” and “GaN Nanorod Growth Conditions and The Applications Thereof”, and the contents of which are incorporated herein by reference.

### TECHNICAL FIELD

The application relates to a semiconductor structure, in particular to a light emitting diode (LED) structure having a semiconductor nano-scaled structure formed therein and the manufacturing method thereof.

### DESCRIPTION OF BACKGROUND ART

To form GaN semiconductor nano columns on sapphire or Si substrate is appealing because the semiconductor nano-scaled structures can be dislocation free due to the lateral strain relaxation in the column geometry. Also, GaN based light emitting diode (LED) structure has been grown on semiconductor nano-scaled structures to achieve high crystal quality. However, for device fabrication, a planar geometry is preferred. Therefore, the coalescence overgrowth on such high crystal quality GaN semiconductor nano-scaled structures becomes an important issue. With coalescence overgrowth, the low dislocation density GaN templates for device fabrication can be prepared. GaN semiconductor nano-scaled structures can be grown by molecular beam epitaxy (MBE) and metal organic chemical vapor deposition (MOCVD) with the methods of self organized growth, regrowth on a selective mask, and catalyst assisted growth. To implement semiconductor nano-scaled structures with MOCVD, normally a patterned growth is preferred. Regularly arranged GaN semiconductor nano-scaled structures formed by patterned MOCVD growth with interferometric lithography have been demonstrated. Semiconductor nano-scaled structures growth followed by coalescence overgrowth with MBE has also been reported. Recently, MOCVD coalescence overgrowth of MBE grown self organized GaN semiconductor nano-scaled structures on Si substrate was also reported. However, further improvement of the quality of the overgrown layer is needed. The quality of the overgrown layer depends on the quality of the semiconductor nano-scaled structures array, including its regularity.

### SUMMARY OF THE DISCLOSURE

A light emitting diode device is disclosed and comprises a substrate having a first growth surface and a bottom surface opposite to the first growth surface; a dielectric layer with a plurality of openings therein formed on the first growth surface; a plurality of semiconductor nano-scaled structures formed on the substrate protruding through the openings; a layer formed on the plurality of semiconductor nano-scaled structures with a second growth surface substantially parallel with the bottom surface; and a light emitting diode structure formed on the second growth surface; wherein the diameters of the openings are smaller than 250 nm, and wherein the diameters of the plurality semiconductor nano-scaled structures are larger than the diameters of the corresponding openings.

### BRIEF DESCRIPTION OF THE DRAWINGS

The accompanying drawings are included to provide easy understanding of the application, and are incorporated herein and constitute a part of this specification. The drawings illustrate embodiments of the application and, together with the description, serve to illustrate the principles of the application.

FIG. 1 illustrates a substrate with a plurality of semiconductor nano-scaled structures thereon.

FIG. 2 depicts an exemplary process for forming a plurality of semiconductor nano-scale structures and/or a semiconductor nano-scaled structure array using a pulsed growth mode in accordance with the present teachings.

FIGS. 3A-3D illustrate scanning electron microscopy (SEM) images of the top-view of the semiconductor nano-scaled structure substrate with different growth temperatures respectively.

FIGS. 4A-4D illustrate scanning electron microscopy (SEM) images of the top-view of the semiconductor nano-scaled structure substrate with different purge durations respectively.

FIG. 5 illustrates a cross-sectional SEM image of the bottom of a GaN semiconductor nano-scaled structure.

FIG. 6 illustrates a substrate with a plurality of semiconductor nano-scaled structures and a coalescence overgrowth layer thereon.

FIGS. 7A-7D illustrate top-view scanning electron microscopy (SEM) images of the dielectric SiO₂ layer with different opening sizes respectively.

FIGS. 8A-8B show the charts with normalized integrated PL intensities as functions of temperature of various samples.

FIG. 9A illustrates a multiple quantum well (MQW) structure with a plurality of semiconductor nano-scaled structures therein.

FIG. 9B illustrates a multiple quantum well (MQW) light emitting diode (LED) structure with a plurality of semiconductor nano-scaled structures therein.

FIG. 10A shows the temperature-dependent integrated PL intensity of various light emitting quantum well (QW) structures.

FIG. 10B shows the temperature-dependent integrated PL intensity of various light emitting diode (LED) structures.

FIG. 10C shows the electroluminescence intensity variations with the injection current (L-I curves) of various light emitting diode (LED) structures.

### DETAILED DESCRIPTION OF PREFERRED EMBODIMENTS

The embodiments are described hereinafter in accompany with drawings.

One embodiment of the present disclosure comprises steps of providing a growth substrate for growing a light emitting structure thereon, and the suitable substrate includes but is not limited to germanium (Ge), gallium arsenide (GaAs), indium phosphide (InP), sapphire, silicon carbide (SiC), silicon (Si), lithium aluminum oxide (LiAlO₂), zinc oxide (ZnO), gallium nitride (GaN), aluminum nitride (AlN), glass, composite, diamond, CVD diamond, diamond-like carbon (DLC) and so on.

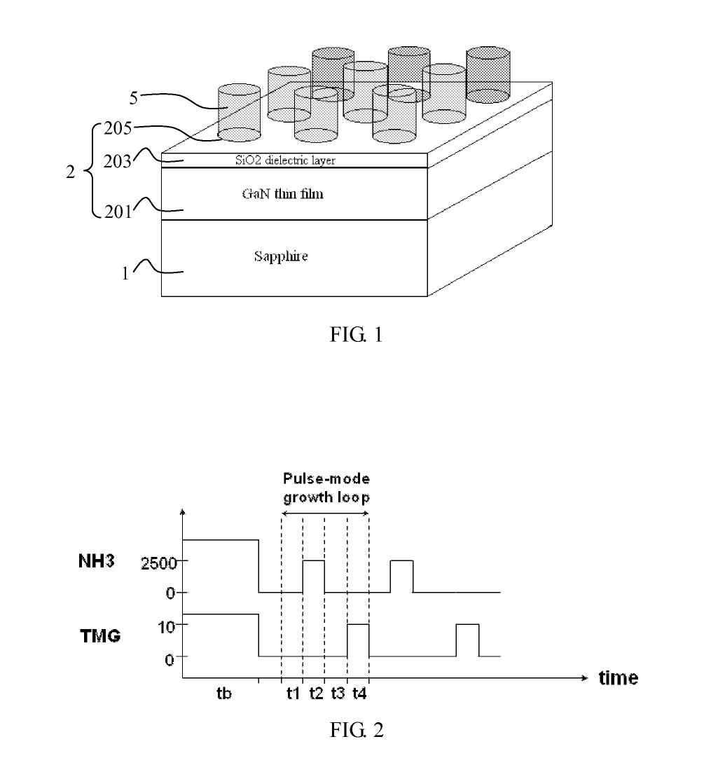

As shown in FIG. 1, to prepare the pattern for semiconductor nano-scaled structures like a semiconductor nano columns 5 grown on a GaN template 2 which comprises a GaN thin film buffer layer 201 with a thickness of 2 μm grown at 1050° C. after the GaN nucleation layer (not shown) of 40 nm grown at 530° C. on the c-plane of the sapphire substrate 1, a dielectric SiO₂ layer 203 of 80 nm in thickness was deposited at 300° C. with plasma enhanced chemical vapor deposition (PECVD). Besides SiO₂, the mask layer 203 could also be formed by other dielectric material such as SiNₓ, Al₂O₃, and so on.

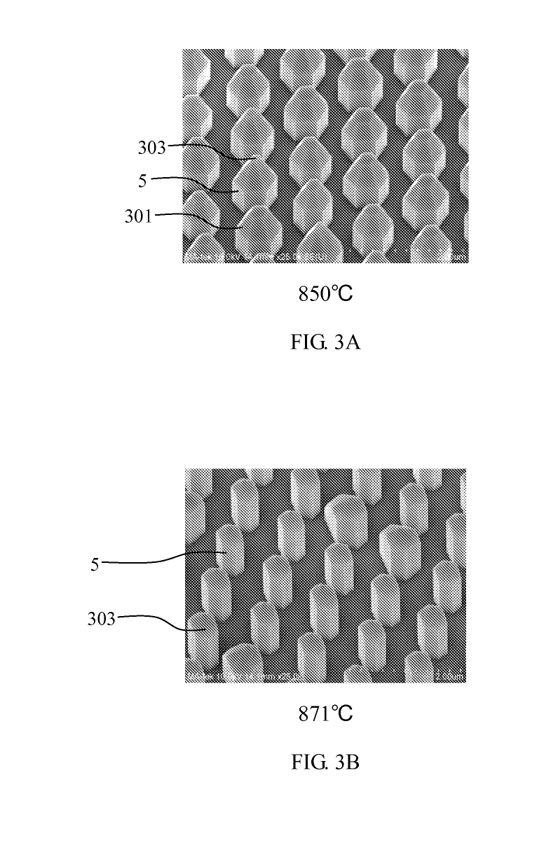

Then, the nanoimprint lithography was applied to form circular openings 205 with 250 nm in diameter and 500 nm in distance between the centers of the two nearest neighboring openings arranged in a the hexagonal pattern on the dielectric SiO₂ layer 203. The shape of the openings is not limited to be circular, and the same single template with multiple different shapes could also be formed. At the beginning of MOCVD growth, the process temperature was set at 1050° C. with a chamber pressure of 100 torr and a V/III ratio (the molar concentration ratio of the ammonia (NH₃) gas to trimethylgallium (TMGa) gas) of 1100. Five seconds after the growth process starts, a GaN base layer (not shown) is formed by a non-pulsed growth mode with trimethylgallium (TMGa) in a flow rate of 15 SCCM and ammonia (NH₃) in a flow rate of 10000 SCCM (SCCM denotes cubic centimeter per minute at STP) provided at the same time. Finally, the growth mode changes to a pulsed mode with the gas of trimethylgallium (TMGa) and ammonia (NH₃) alternately modulated to turn on or off for growing the semiconductor nano columns 5. The pulse loop of the alternately on/off flowing gases is shown in details in both the following steps and FIG. 2:

[step1]: NH3 off, TMG off, t1=15 seconds;

[step2]: NH3 on, TMG off, t2=15 seconds, NH3=2500 SCCM;

[step3]: NH3 off, TMG off, t3=15 seconds;

[step4]: NH3 off, TMG on, t4=15 seconds, TMG=12 SCCM.

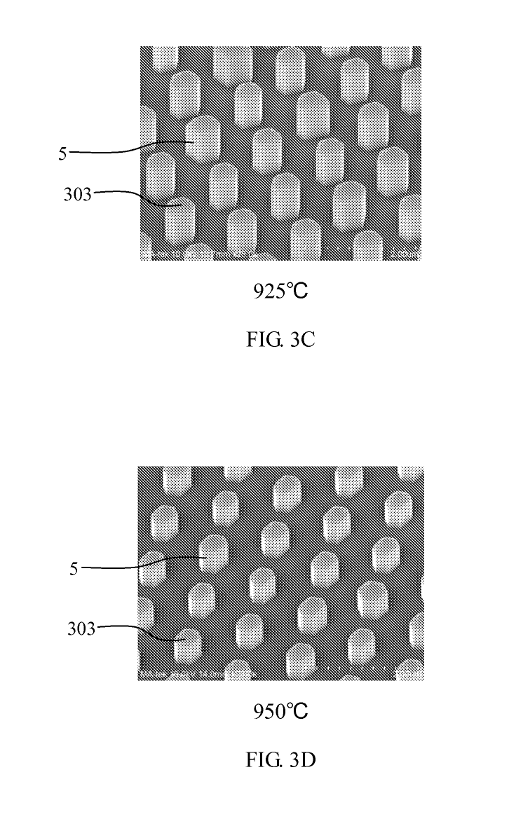

According to the growth conditions provided above, the growth temperature modulation experiment in accordance with four different growth conditions as the growth temperature in the pulse loop process are controlled under the process temperature of 850° C., 871° C., 925° C. and 950° C., respectively. FIGS. 3A-3D show the scanning electron microscopy (SEM) images of the hexagonally arranged GaN semiconductor nano columns 5 based on the four different growth temperature conditions. As shown in the figures, when pulse growth temperature is low (lower than 850° C. as indicated in FIG. 3A), the shape of the semiconductor nano column 5 becomes shorter and wider, and the {10-11} incline 301 becomes more apparent. The {10-11} incline 301 is one of the lattice surface of the GaN crystal structure, which can inhibit the semiconductor nano columns from growing upward and degrading the quality and uniformity of the substrate. When the pulse growth temperature raises (higher than 850° C. as indicated in FIG. 3A), the growth surface (top surface) 303 of the semiconductor nano column 5 becomes flatter and the semiconductor nano column 5 is longer. Therefore, the quality of the semiconductor nano columns becomes better. But when the pulse growth temperature reaches to certain temperature (higher than 950° C. as indicated in FIG. 3D), the shape of the semiconductor nano column becomes shorter and wider again.

When the pulse growth temperature is lower than 850° C., the surface mobility of the Ga element in the flowing gas decreases, the amount of the Ga element moving to the growth surface 303 of the semiconductor nano column 5 decreases and leads to the formation of the {10-11} incline 301, which inhibits the semiconductor nano column 5 from growing upward. When pulse growth temperature increases, the surface mobility of the Ga element moving to the growth surface 303 of the semiconductor nano column 5 increases and the probability the Ga element on the dielectric SiO₂ mask layer 203 captured by the sidewalls of the semiconductor nano column 5 can decrease. (Large amount of Ga elements captured by sidewalls of the semiconductor nano column 5 may widen the side wall), and the semiconductor nano column 5 becomes longer with a flatter top surface 303. But when the growth temperature is too high (higher than 950° C. as indicated in FIG. 3D), the GaN can decompose. Therefore, according to the experimental results, it is preferred to have the growth temperature of between 850° C. and 950° C. during the pulse growth mode.

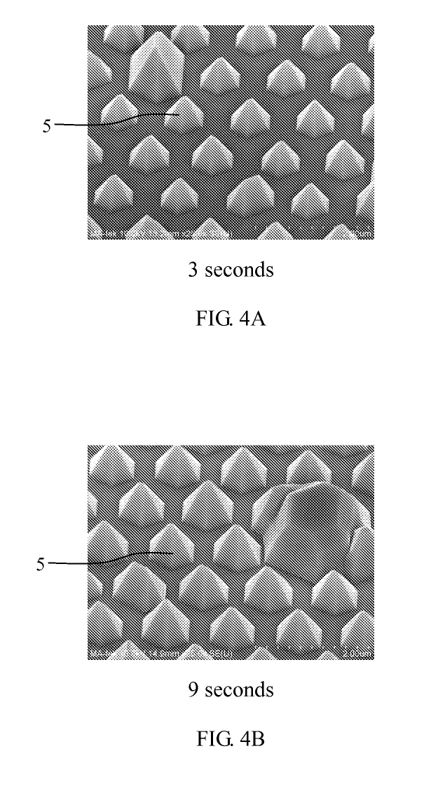

Besides, the purge duration (step 1 and step 3 as the pulse loop details mentioned above) experiments are also monitored. Four different purge durations, 3 seconds, 9 seconds, 15 seconds, and 24 seconds are controlled, respectively. As shown in FIGS. 4A-4D, while extending the purge duration (t1 and t3 in FIG. 2), the growth surface of the semiconductor nano column 5 changes from the {10-11} incline to the flat top surface. In the experiments, decreasing the purge duration means decreasing the surface diffusion length for the Ga element, which leads the formation of the {10-11} incline that suppresses the semiconductor nano column to grow upward. Therefore, according to the experimental results, it is preferred to have the purge duration longer than 15 seconds. Besides, the growth temperature (850° C.-950° C. during the pulse growth mode) is high to the semiconductor nano column 5 which may decompose GaN. Therefore, the whole pulse growth procedure, including the purge time, should not be too long (less than 60 seconds is preferred) to decompose the semiconductor nano column structure 5. Therefore, It is preferred to have the pulse growth purge duration between 15 seconds and 60 seconds.

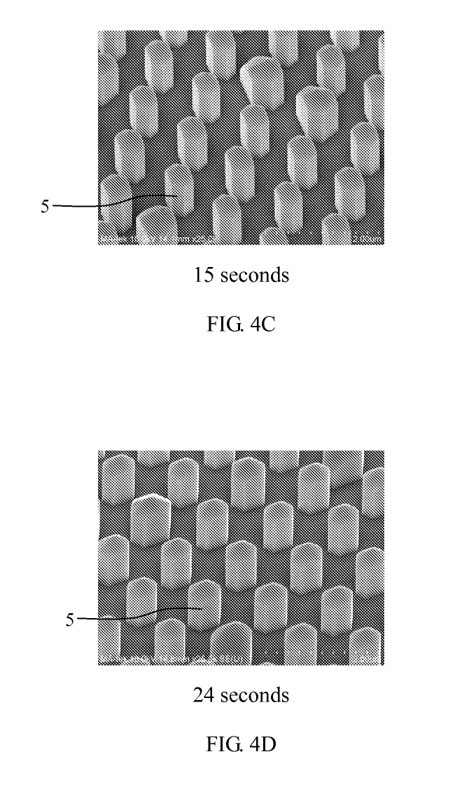

In FIG. 5, a cross-sectional SEM image of the bottom of a GaN semiconductor nano-scaled structures 5 are shown. Here, the bottom edges of the slanted walls of the dielectric SiO₂ masks (80 nm in thickness) define the opening diameter (hole) of 250 nm. The width of the semiconductor nano-scaled structure (300 nm) is larger than the diameter of the opening because of the lateral growth.

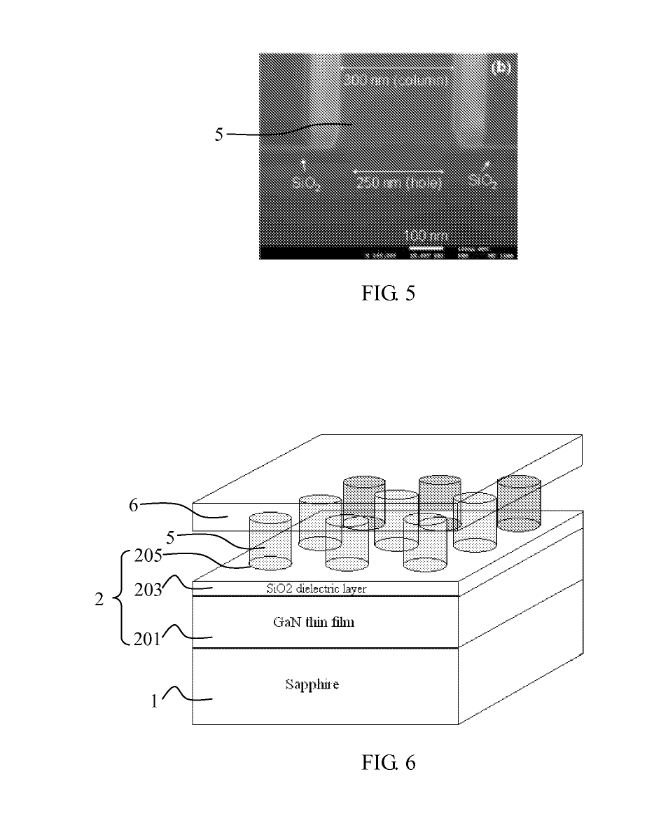

After the semiconductor nano-scaled structures 5 are formed, the coalescence overgrowth procedure follows. The chamber pressure and V/III ratio (the molar concentration ratio of the ammonia (NH₃) gas to trimethylgallium (TMGa) gas) were changed to 200 torr and 3900, respectively, while the growth temperature is kept at 1050° C. The continuous flow rates of TMGa and NH₃ are 3.5 μmol/min and 1500 SCCM, respectively. Under such growth conditions, the growth rate is about 1.3 μm/hour, and the coalescence overgrowth for 90 minutes leads to an overgrown layer 6 of about 2 μm in thickness, as shown in FIG. 6.

To demonstrate the improved quality of the coalescence overgrowth layer 6 on semiconductor nano-scaled structures 5, a sample of the aforementioned GaN template 2 for nanoimprint process was used as the control sample for comparison.

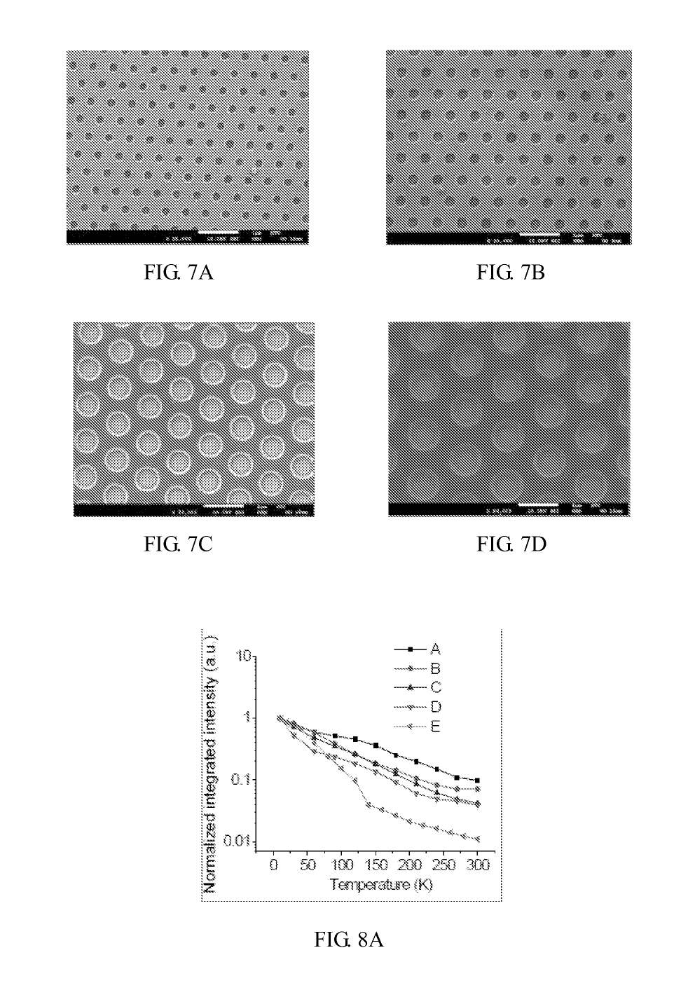

To compare the coalescence overgrowth quality between the conditions of different opening diameter and spacing sizes for understanding the threading dislocation evolution behaviors, four templates of different opening diameter patterns were prepared for growing semiconductor nano-scaled structures. The templates 2 are fabricated with similar aforementioned method. A GaN thin film 201 with a thickness of 2 μm is formed on the c-plane sapphire substrate 1, and a plurality of hexagonally arranged openings fabricated with nanoimprint lithography and reactive ion etching are formed in a dielectric SiO₂ layer 203 which is about 80 nm in thickness on the GaN thin film layer 201. The four opening patterns include the opening diameters of 250, 300, 450, and 600 nm with the corresponding spacing distances, which are defined as the distances between the centers of the two nearest neighboring openings, of 500, 600, 900 and 1200 nm as shown in FIGS. 7A-7D, respectively. The semiconductor nano-scaled structure samples based on the openings of 250, 300, 450, and 600 nm in opening diameter are designated as samples A, B, C and D, respectively. Besides, the coalescence overgrowth samples based on semiconductor nano-scaled structure samples A-D are designated as samples AO-DO, correspondingly.

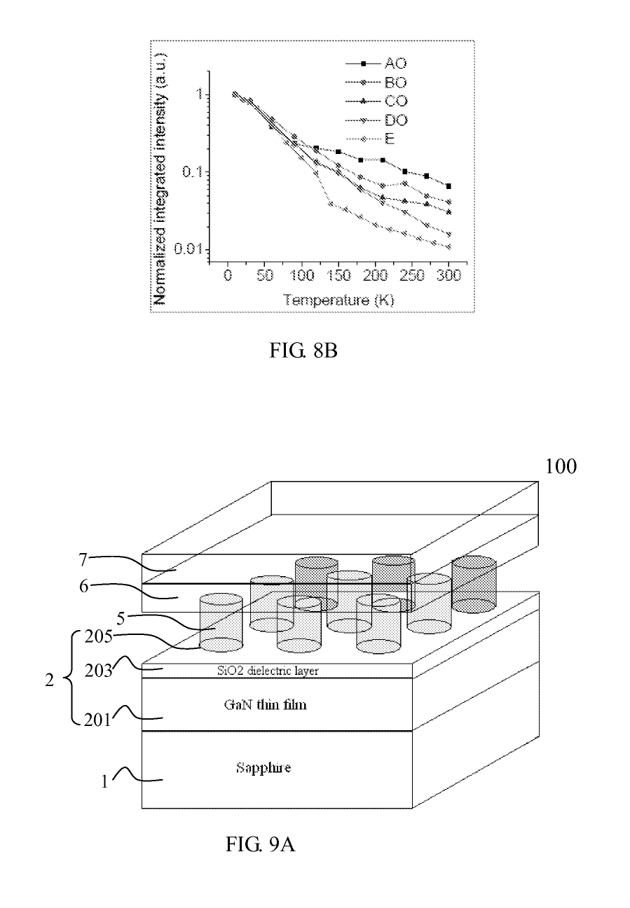

FIGS. 8A and 8B show the normalized integrated PL intensities as functions of temperature of various samples for comparison. The ratio of the normalized integrated intensity at room temperature to the normalized integrated intensity at 10 K (Kelvin temperature) can be regarded as a representation of internal quantum efficiency (IQE), which is related to the defect density of a sample. In FIGS. 8A and 8B, the comparisons of integrated PL intensity between the semiconductor nano-scaled structure samples (A-D) and between the overgrowth samples (AO-DO), respectively, are demonstrated. In each part, the comparison with the GaN template (sample E, without semiconductor nano-scaled structures) is also illustrated.

Here, one can see the trend of decreasing IQE with increasing semiconductor nano-scaled structure size in either semiconductor nano-scaled structure or overgrowth sample groups. In all the semiconductor nano-scaled structures and overgrowth samples, the IQE values are always higher than that (1.1%) of the GaN template (sample E, without semiconductor nano-scaled structures), indicating the higher crystal quality of semiconductor nano-scaled structure growth and coalescence overgrowth. Also, for each size of the semiconductor nano-scaled structures, the IQE value of the overgrowth sample is always lower than that of the corresponding semiconductor columns sample. In other words, new defects can be formed during coalescence overgrowth. With the opening size of 250 nm, the semiconductor nano-scaled structure sample A has an IQE of 9.9%, which is nine times that of the GaN template (sample E, without semiconductor nano-scaled structures). Also, the corresponding overgrowth sample has an IQE of 6.7%, which is about six times that of the GaN template (sample E, without semiconductor nano-scaled structures).

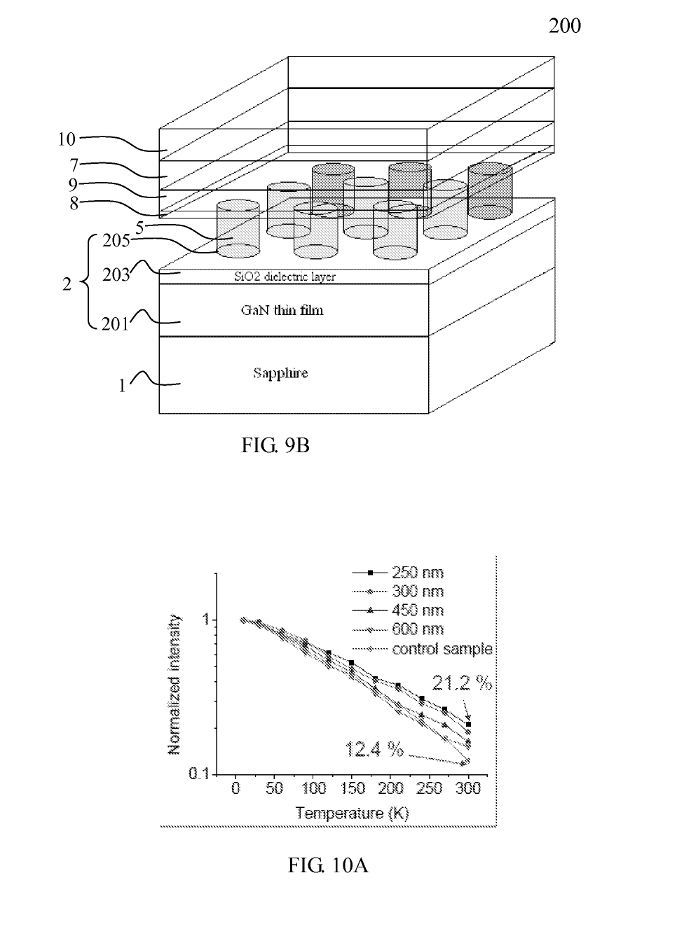

As shown in FIGS. 9A and 9B, to further demonstrate the improved quality of a coalescence overgrown GaN template, a multiple InGaN/GaN quantum well (QW) structure 100 and quantum well (QW) light emitting diode (LED) structure 200 on the tops of the GaN templates 2 of various semiconductor nano-scaled structure sizes are prepared for comparing their emission efficiencies with that of the control sample. A five-period light emitting quantum well (QW) structure 7 was grown on the GaN template 2. The five-period light emitting quantum well (QW) structure 7 means the structure 7 comprises the well layers and barrier layers stacked alternately for five times, as shown in FIG. 9A. In a preferred embodiment, the QW structure comprises five pairs of 3 nm InGaN well layer and 15 nm GaN barrier layer grown at 675° C. and 850° C. respectively. For growing the light emitting diode (LED) 200 on the semiconductor nano-scaled structure layer 5 with 1 μm in thickness, an undoped GaN layer 8 of 1 μm in thickness and an n-GaN layer 9 of 4 μm in thickness is deposited with silicon dopants at 1050° C. Following the five periods of undoped quantum well (QW) structure 7, a 120 nm p-GaN layer 10 is grown at 930-C.

For different main emission wavelengths of the light emitting diode (LED) structures 200, the growth temperature of the quantum well (QW) structure 7 is also different. In the blue (green) light emitting diode (LED) structure 200, the 3 nm InGaN well layers and 15 nm GaN barrier layers are grown at 715 (675) 0° C. and 850 (850) 0° C., respectively, to form main emitting peak of about 460 (about 520) nm in wavelength, as shown in FIG. 9B. In addition, the growth surface of substrate could also be roughened to enhance the light extraction efficiency.

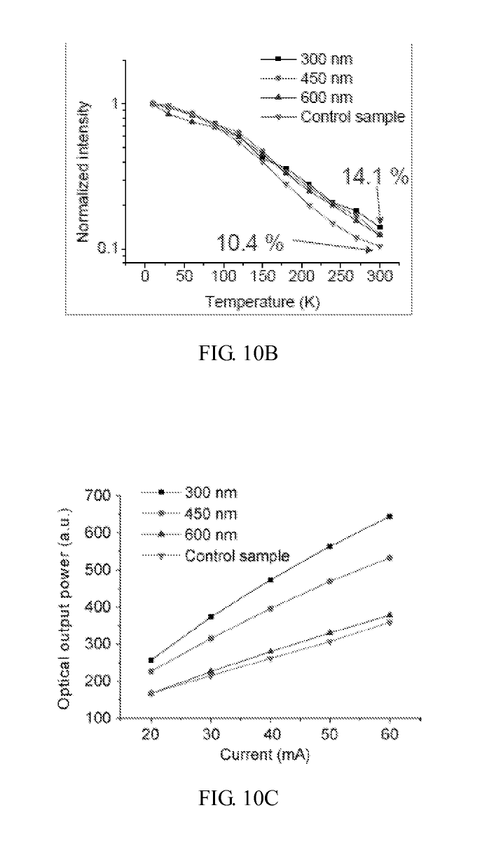

FIG. 10A shows the temperature-dependent integrated PL intensity of the emitting quantum well (QW) structures 100 based on semiconductor nano-scaled structures of 250, 300, 450, and 600 nm in opening diameter. For comparison, the result of the quantum well (QW) structure grown on the control GaN template 2 without the semiconductor nano-scaled structure under the same quantum well (QW) growth conditions is also shown. Here, one can see that the IQEs, which are defined as the ratios of integrated PL intensities at 300 K (Kelvin temperature) to the integrated PL intensities at 12 K (Kelvin temperature), are 21.2%, 19.0%, 16.5%, and 15.3% for the quantum well (QW) samples based on the semiconductor nano-scaled structures of 250, 300, 450, and 600 nm in opening diameter, respectively. All those IQE values are significantly higher than that of the control sample of 12.4%. Such comparisons clearly indicate the advantages of reducing threading dislocation density and improving crystal quality by semiconductor nano-scaled structure coalescence overgrowth. A better overgrown layer quality leads to the higher overgrown quantum well (QW) emission efficiency.

FIG. 10B shows the temperature-dependent integrated PL intensities of the light emitting diode (LED) structures based on the semiconductor nano-scaled structures of 300, 450, and 600 nm in opening diameter. Again, the result of the corresponding control sample is also shown. In these comparisons, the calibrated IQE values in the light emitting diodes (LEDs) based on the semiconductor nano-scaled structures of 300, 450, and 600 nm in opening diameter are 49.2%, 36.6%, and 19.2%, respectively. Comparing with the corresponding control sample, which has the 20.1% IQE value, it shows that except the case of 600 nm in opening diameter, the emission efficiency of an overgrown light emitting diode (LED) is significantly enhanced, and it is expected that the efficiency can be further enhanced if the semiconductor nano-scaled structure has smaller opening diameter.

FIG. 10C shows the electroluminescence intensity variations with the injection current (L-I curves) of the light emitting diode (LED) structures based on the semiconductor nano-scaled structures of 300, 450, and 600 nm in opening diameter. Here, one can see that the light emitting diode (LED) output intensities are enhanced by using the semiconductor nano-scaled structures overgrowth templates. At 60 mA of injection current, the light emitting diode (LED) based on 300 nm semiconductor opening size can deliver an output intensity about double than the output intensity of the corresponding control sample without semiconductor nano-scaled structures.

Taking the light-emitting diode structure as an example, the emission spectrum of the transferred light could also be adjusted by changing the physical or chemical arrangement of one layer or more layers in the optoelectronic system. The commonly used materials are the series of aluminum gallium indium phosphide (AlGaInP), the series of aluminum gallium indium nitride (AlGaInN), the series of zinc oxide (ZnO) and so on. The structure of the active layer can be a single heterostructure (SH), a double heterostructure (DH), a double-side double heterostructure (DDH), or a multi-quantum well (MQW). Besides, except for adjusting the growth temperature mentioned above, the wavelength of the emitting light could also be adjusted by changing the number of the periods of the quantum well.

It will be apparent to those having ordinary skill in the art that various modifications and variations can be made to the devices in accordance with the present disclosure without departing from the scope or spirit of the disclosure. Such as the material of the semiconductor nano columns mentioned in the embodiment is not limited thereto, any semiconductor material with hexagonal wurtzite structure could also be formed. In view of the foregoing, it is intended that the present disclosure covers modifications and variations of this disclosure provided they fall within the scope of the following claims and their equivalents.

What is claimed is:

1. A light-emitting device, comprising:
a substrate comprising a first growth surface and a bottom surface opposite to the first growth surface;
a dielectric layer with a plurality of openings therein formed on the first growth surface;
a plurality of semiconductor nano-scaled structures formed on the substrate protruding through the openings;
a layer formed on the semiconductor nano-scaled structures with a second growth surface substantially parallel with the bottom surface; and
a light emitting diode structure formed on the second growth surface;
wherein the diameter of at least one of the openings is smaller than 250 nm, and wherein a dimension of one of the plurality semiconductor nano-scaled structures is larger than the diameter of the corresponding openings.

2. The light-emitting diode device as claimed in claim 1, wherein the semiconductor nano-scaled structures are substantially hexagonal columns.

3. The light-emitting diode device as claimed in claim 1, wherein the semiconductor nano-scaled structures are hexagonally arranged.

4. The light-emitting diode device as claimed in claim 1, the first growth surface is a rough surface.

5. The light-emitting diode device as claimed in claim 1, further comprising a buffer layer formed between the substrate and the dielectric layer.

6. The light-emitting diode structure as claimed in claim 5, wherein the buffer layer and the semiconductor nano-scaled structures substantially comprise the same material.

7. The light-emitting diode structure as claimed in claim 1, wherein the structure of the semiconductor nano-scaled structures is a wurtzite structure.
